(19) United States
(12) Patent Application Publication
(10) Pub. No.: US 2014/0132882 A1
(43) Pub. Date: May 15, 2014

(54) LIQUID CRYSTAL DISPLAY, BACKLIGHT MODULE AND LIGHT-EMITTING DIODE ASSEMBLY THEREOF

(71) Applicant: InnoLux Corporation, Miao-li County (TW)

(72) Inventors: Ming-Feng Hsieh, Miao-Li County (TW); Shih-Chang Huang, Miao-Li County (TW)

(73) Assignee: InnoLux Corporation, Miao-Li County (TW)

(21) Appl. No.: 14/069,595

(22) Filed: Nov. 1, 2013

(30) Foreign Application Priority Data
Nov. 9, 2012 (TW) 101141730

(51) Int. Cl. G02F 1/1335; H01L 33/48; H01L 33/50

(52) U.S. Cl. CPC G02F 1/133603; H01L 33/508; H01L 33/483
USPC 349/61; 257/89

(57) ABSTRACT

A light-emitting diode (LED) assembly is provided, including a package, a blue LED and a green LED disposed in the package, and a red phosphor layer at least covering the blue LED. The thickness of the red phosphor layer on the blue LED is greater than that of a phosphor layer on the green LED.

### CROSS REFERENCE TO RELATED APPLICATIONS

The present application claims priority of Taiwan Patent Application No. 101141730, filed on Nov. 9, 2012, the entirety of which is incorporated by reference herein.

### BACKGROUND OF THE INVENTION

1. Field of the Invention

The present application relates to a light-emitting diode (LED) assembly, and in particular, relates to a liquid crystal display and a backlight module including the same.

2. Description of the Related Art

For satisfying the requirements of a display with high color gamut, a blue light-emitting diode (LED) chip with green and red phosphor layers (i.e. B+RG LED) is usually used for an LED backlight source of liquid crystal displays (LCDs), but now still limited to achieve higher color gamut.

Generally, a RGB LED is alternatively used for solving the problem to achieve high color gamut. However, some problems such as complicate circuit design for the three colors chips, different illumination efficiency decay rates for the chips, and difficult wire bonding etc. may cause the RGB LED to become unstable. Specifically, the green LED chip having obvious lower illumination efficiency than the blue LED chip is further troublesome. Thus, how to solve the aforesaid problems is worth thinking for relevant staffs.

### BRIEF SUMMARY OF THE INVENTION

The invention provides a light-emitting diode (LED) assembly and the application thereof that the light extraction efficiency of the LEDs thereof can be enhanced, so as to satisfy the requirements of a display with higher color gamut.

An embodiment of the invention provides an LED assembly, comprising a package, a blue LED and a green LED disposed in the package, and a red phosphor layer at least covering the blue LED. The thickness of the red phosphor layer on the blue LED is greater than that of a phosphor layer on the green LED.

In an embodiment, the package forms a receiving space including an inclined surface with the blue and green LEDs disposed thereon, and the red phosphor layer and the phosphor layer form a light-emitting surface, wherein an inclined angle is formed between the inclined surface and the light-emitting surface, and the green LED is closer to the light-emitting surface than the blue LED.

In an embodiment, the package forms a receiving space and includes a pad, and the red phosphor layer and the phosphor layer form a light-emitting surface, wherein the pad and the blue LED are disposed in the receiving space, and the green LED is disposed on the pad and closer to the light-emitting surface than the blue LED.

In an embodiment, the package forms two receiving spaces with the blue and green LEDs respectively disposed therein.

In an embodiment, the quantity of red particles in the phosphor layer on the green LED is zero.

In an embodiment, the thickness of the phosphor layer on the green LED is zero.

In an embodiment, the blue and green LEDs are disposed at the same height.

In an embodiment, the receiving spaces are bowl-shaped recesses.

Another embodiment of the invention provides a backlight module, comprising a back plate and at least one LED assembly disposed thereon. The LED assembly comprises a package, a blue LED and a green LED disposed in the package, and a red phosphor layer at least covering the blue LED. The thickness of the red phosphor layer on the blue LED is greater than that of a phosphor layer on the green LED.

Yet another embodiment of the invention provides a liquid crystal display, comprising a liquid crystal panel and a backlight module disposed on a side thereof. The backlight module comprises a back plate and at least one LED assembly disposed thereon. The LED assembly comprises a package, a blue LED and a green LED disposed in the package, and a red phosphor layer at least covering the blue LED. The thickness of the red phosphor layer on the blue LED is greater than that of a phosphor layer on the green LED.

### BRIEF DESCRIPTION OF THE DRAWINGS

The invention can be more fully understood by reading the subsequent detailed description and examples with references made to the accompanying drawings, wherein:

FIG. 1 is a sectional view of an LED assembly according to an embodiment of the invention;

FIG. 2 is a sectional view of an LED assembly according to another embodiment of the invention;

FIG. 3 is a sectional view of an LED assembly according to yet another embodiment of the invention; and

FIG. 4 is an exploded diagram of a liquid crystal display according to an embodiment of the invention.

### DETAILED DESCRIPTION OF THE INVENTION

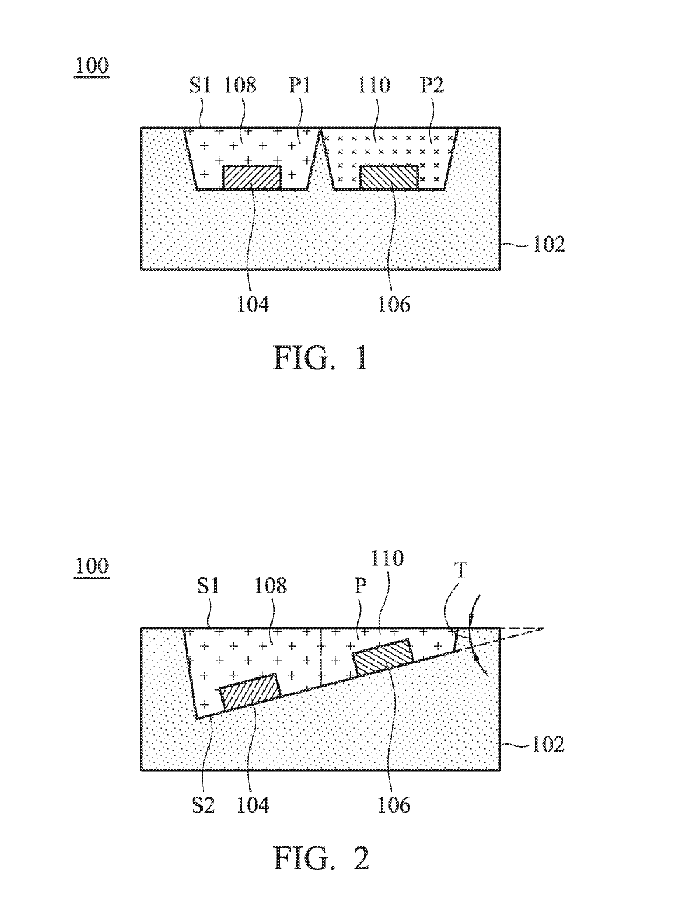

FIG. 1 is a sectional view of a light-emitting diode (LED) assembly according to an embodiment of the invention. As shown in FIG. 1, the LED assembly 100 primarily comprises a package 102, a blue LED 104, a green LED 106, and a red phosphor layer 108. The package 102 forms two bowl-shaped receiving spaces P1 and P2 with the blue and green LEDs 104 and 106 respectively disposed therein and substantially disposed at the same height.

It is shown that a red phosphor layer 108 covers the blue LED 104, and a phosphor layer 110 covers the green LED 106. The red phosphor layer 108 and the phosphor layer 110 form a light-emitting surface S1, and the thickness of the red phosphor layer 108 is greater than or equal to that of the phosphor layer 110. In some embodiments, the quantity of red phosphor particles in the phosphor layer 110 may be zero, and there may be no phosphor layer on the green LED 106, i.e. the thickness of the phosphor layer 110 is zero. According to the aforesaid structural features, the light absorbed by the phosphor layer 110 from the green LED 106 can be less than that absorbed by the red phosphor layer 108 from the blue LED 104. Thus, the problem of obvious illumination efficiency difference between the green and blue LEDs can be overcome, so as to enhance the light extraction efficiency of the entire LED assembly.

FIG. 2 is a sectional view of an LED assembly according to another embodiment of the invention. As shown in FIG. 2, the LED assembly 100 includes a receiving space P, and the bottom side of the receiving space P forms an inclined surface S2 with a blue LED 104 and a green LED 106 disposed thereon. A red phosphor layer 108 covers the blue LED 104, and a phosphor layer 110 covers the green LED 106. In this embodiment, the phosphor layer 110 and the red phosphor layer 108 have the same material with red phosphor particles. The red phosphor layer 108 and the phosphor layer 110 form a light-emitting surface S1, and an inclined angle T is formed between the inclined surface S2 and the light-emitting surface S1. Thus, the green LED 106 can be closer to the light-emitting surface S1 than the blue LED 104, and the illumination energy absorbed by the red phosphor layer 108 from the green LED 106 can be reduced accordingly.

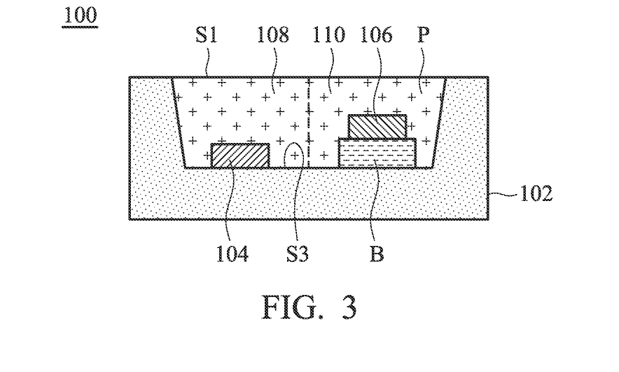

Referring to FIG. 3, an LED assembly 100 according to yet another embodiment of the invention includes a receiving space P having a bottom surface S3 with a pad B and a blue LED 104 disposed thereon. In addition, a green LED 106 is disposed on the pad B. Thus, the green LED 106 can be also closer to the light-emitting surface S1 than the blue LED 104 due to the stacked structure, to reduce the illumination energy absorbed by the red phosphor layer 108 from the green LED 106.

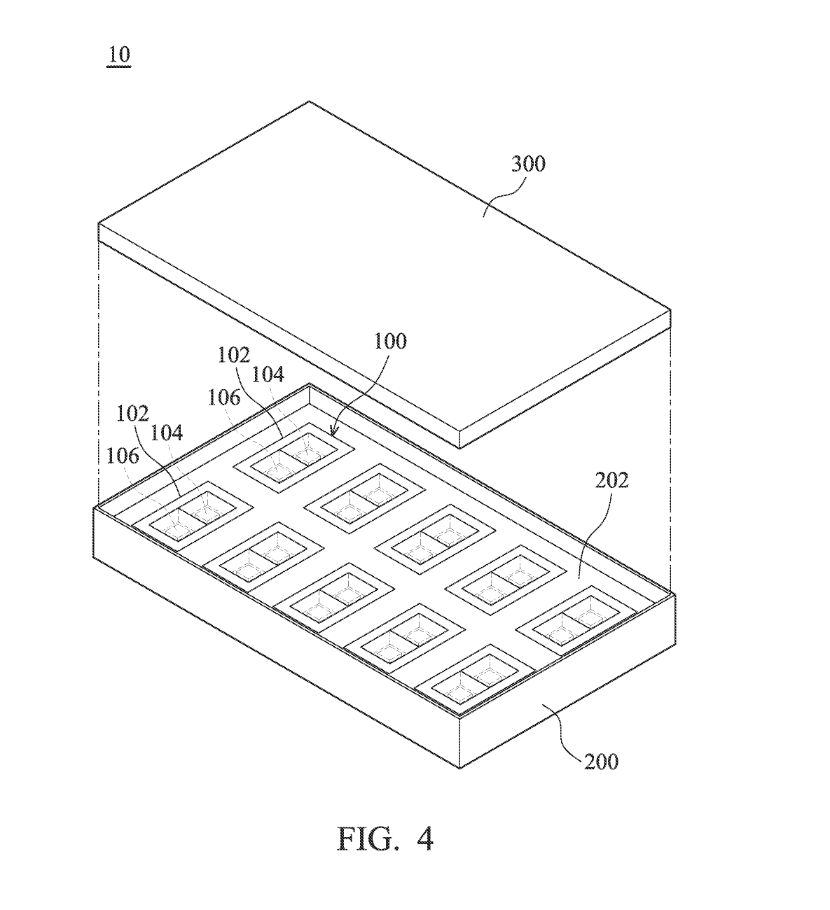

The aforesaid LED assembly 100 of different embodiments may be applied to a backlight module for a liquid crystal display (LCD). FIG. 4 is an exploded diagram of a liquid crystal display according to an embodiment of the invention. The LCD 10 comprises a backlight module 200 and a liquid crystal panel 300. The backlight module 200 is disposed on the rear side of the liquid crystal panel 300 for supplying a backlight. As shown in FIG. 4, the backlight module 200 is a direct-type backlight module, comprising a back plate 202 with a plurality of the LED assemblies 100 disposed thereon. In some embodiments, the backlight module 200 may also be an edge-type backlight module.

As mentioned above, the invention provides an LED assembly and the application thereof The LED assembly comprises a package, a blue LED and a green LED disposed in the package, and a red phosphor layer at least covering the blue LED, wherein the thickness of the red phosphor layer on the blue LED is greater than that of a phosphor layer on the green LED. According to the aforesaid structural features, the light extraction efficiency of the entire LED assembly can be enhanced to satisfy the requirements of a display with higher color gamut.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting diode assembly, comprising:
a package;
a blue light-emitting diode, disposed in the package;
a green light-emitting diode, disposed in the package; and
a red phosphor layer, at least covering the blue light-emitting diode, wherein the thickness of the red phosphor layer on the blue light-emitting diode is greater than that of a phosphor layer on the green light-emitting diode.

2. The light-emitting diode assembly as claimed in claim 1, wherein the package forms a receiving space including an inclined surface with the blue and green light-emitting diodes disposed thereon, and the red phosphor layer and the phosphor layer form a light-emitting surface, wherein an inclined angle is formed between the inclined surface and the light-emitting surface, and the green light-emitting diode is closer to the light-emitting surface than the blue light-emitting diode.

3. The light-emitting diode assembly claimed in claim 1, wherein the package forms a receiving space and includes a pad, and the red phosphor layer and the phosphor layer form a light-emitting surface, wherein the pad and the blue light-emitting diode are disposed in the receiving space, and the green light-emitting diode is disposed on the pad and closer to the light-emitting surface than the blue light-emitting diode.

4. The light-emitting diode assembly as claimed in claim 1, wherein the package forms two receiving spaces with the blue and green light-emitting diodes respectively disposed therein.

5. The light-emitting diode assembly as claimed in claim 1, wherein the quantity of red particles in the phosphor layer on the green light-emitting diode is zero.

6. The light-emitting diode assembly as claimed in claim 1, wherein the thickness of the phosphor layer on the green light-emitting diode is zero.

7. The light-emitting diode assembly as claimed in claim 4, wherein the blue and green light-emitting diodes are disposed at the same height.

8. The light-emitting diode assembly as claimed in claim 4, wherein the receiving spaces are bowl-shaped.

9. A backlight module, comprising:
a back plate; and
at least one light-emitting diode assembly disposed on the back plate, comprising:
a package;
a blue light-emitting diode, disposed in the package;
a green light-emitting diode, disposed in the package; and
a red phosphor layer, at least covering the blue light-emitting diode,
wherein the thickness of the red phosphor layer on the blue light-emitting diode is greater than that of a phosphor layer on the green light-emitting diode.

10. A liquid crystal display, comprising:
a liquid crystal panel; and
a backlight module disposed on a side of the liquid crystal panel, comprising:
a back plate; and
at least one light-emitting diode assembly disposed on the back plate, comprising:
a package;
a blue light-emitting diode, disposed in the package;
a green light-emitting diode, disposed in the package; and
a red phosphor layer, at least covering the blue light-emitting diode, wherein the thickness of the red phosphor layer on the blue light-emitting diode is greater than that of a phosphor layer on the green light-emitting diode.
